(19) United States
(12) Patent Application Publication
(10) Pub. No.: US 2010/0028789 A1
(43) Pub. Date: Feb. 4, 2010

(54) METHOD OF CONTROLLING EXPOSURE DEVICE, METHOD OF FABRICATING SEMICONDUCTOR, AND PHOTOMASK

(76) Inventors: Satoshi NAGAI, Kanagawa (JP); Kazuya Fukuhara, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/533,182

(22) Filed: Jul. 31, 2009

(30) Foreign Application Priority Data
Jul. 31, 2008 (JP) 2008-197732

(51) Int. Cl. G03F 1/00; H01L 21/027

(52) U.S. Cl. 430/5; 430/319

(57) ABSTRACT

A method of controlling exposure device according to an embodiment includes preparing a photomask in which a check pattern is formed, wherein the check pattern comprising a plurality of patterns which have a first diameter and a second diameter and have pattern dimensions being changeable after being transferred according to polarization degree of exposure light are arranged in the second diameter direction, irradiating the photomask with the exposure light having a predetermined polarization degree so as to transfer the check pattern to a transferred object, and measuring the dimensions of the images of the check pattern transferred to the transferred object so as to obtain the polarization degree.

### CROSS-REFERENCE TO RELATED APPLICATIONS

This application is based upon and claims the benefit of priority from prior Japanese Patent Application No. 2008-197732, filed on Jul. 31, 2008, the entire contents of which are incorporated herein by reference.

### BACKGROUND

Recently, a semiconductor device is increasingly enhanced in performance due to miniaturization of the device pattern. Generally, the device pattern is formed through an exposure process of transferring a pattern formed on a photomask to photoresist on a processed substrate and an etching process of transferring the resist pattern to the processed substrate. In the exposure process, an exposure device is used that forms an illuminating light by passing a light having a wavelength of almost a hundred nanometer (nm) to several hundreds nm through an illumination optics, irradiates the illuminating light to the photomask, and transfers the pattern formed on the photomask to the photoresist on the processed substrate through a projection optics. Heretofore, in the exposure device, it has been successfully achieved to reduce a transferable size of the pattern on the photomask by shortening the wavelength of exposure light and heightening numeric aperture (NA) of a projection lens in the projection optics (upgrading of NA).

It is largely dependent on an introduction of polarized illumination technology that the transferable size is reduced due to the upgrading of NA of the numeric aperture (NA) of the projection lens. When the numeric aperture (NA) of the projection lens becomes large, a light having a large incident angle to the photoresist which normally can not reach the photoresist can reach the photoresist. The tinier the pattern on the photomask is, the larger the incident angle to the photoresist becomes, so that the upgrading of NA is a necessary condition for forming a tiny pattern. However, it is known that when the numeric aperture (NA) of the projection lens becomes large, a “p” polarization component included in the exposure light decreases a contrast of images formed in the photoresist.

Therefore, in recent years, the polarized illumination technology is built upon a basis of forming an illumination light which includes a “s” polarization component as a main component of the exposure light and developing a photomask, a projection optics and a photoresist material for forming a pattern on the photoresist by using the above-mentioned illumination light. Further, in order to actually fabricate a semiconductor device by using the polarized illumination technology, a technology for controlling the polarization degree of the exposure light has been more important. In recent years, a method of checking the polarization degree has been proposed, the method being capable of regularly measuring the polarization degree of the illumination optics of the exposure device and controlling the polarization degree not to exceed the control limit, for example, disclosed in JP-A-2007-35671.

The method of checking the polarization degree includes steps of disposing a light detector having a polarization filter on a rear surface of a photomask stage of the exposure device, respectively measuring light quantity distributions of the “s” polarization component and the “p” polarization component, and evaluating the polarization degree from the measurement result.

### BRIEF SUMMARY

A method of controlling exposure device according to an embodiment includes preparing a photomask in which a check pattern is formed, wherein the check pattern comprising a plurality of patterns which have a first diameter and a second diameter and have pattern dimensions being changeable after being transferred according to polarization degree of exposure light are arranged in the second diameter direction, irradiating the photomask with the exposure light having a predetermined polarization degree so as to transfer the check pattern to a transferred object, and measuring the dimensions of the images of the check pattern transferred to the transferred object so as to obtain the polarization degree.

A method of fabricating a semiconductor device according to another embodiment includes forming a device pattern on a wafer by using an exposure device in which the polarization degree is controlled by the above-mentioned method of controlling exposure device.

A photomask according to another embodiment includes a device pattern having a line and space pattern arranged in a predetermined direction and a check pattern comprising a plurality of patterns which have a first diameter and a second diameter and are arranged so as to match the second diameter direction to the predetermined direction.

### BRIEF DESCRIPTION OF THE DRAWING

FIG. 1 is a plane view schematically showing one example of a main part of a check pattern used in the embodiment;

FIG. 2 is a plane view schematically showing one example of a photomask used in the embodiment;

FIG. 3 is an explanatory view schematically showing one example of a structure of an exposure device used in the embodiment;

FIG. 4 is a plane view schematically showing one example of an illumination aperture used in the embodiment;

FIG. 5 is an explanatory view schematically showing a principle of two-beam interference;

FIG. 6 is a graph schematically showing a relationship between of polarization degree and DL″/DS″ in order to show a polarization degree-dependency of the check pattern;

FIG. 7 is a graph schematically showing a relationship between of dimension and defocus value in order to show a defocus value-dependency of the check pattern;

FIG. 8 is a graph schematically showing a relationship between of dimension and exposure amount in order to show an exposure amount-dependency of the check pattern;

FIG. 9 is a graph schematically showing a relationship between of dimension and polarization degree in order to show a polarization degree-dependency of the check pattern; and

FIG. 10 is a graph schematically showing a relationship between polarization degree and DL″/DS″ in order to show a polarization degree-dependency of the other check pattern.

### DETAILED DESCRIPTION

The method of controlling exposure device according to the embodiment will be explained in detail below referring to the drawings.

### (1) Preparation of Photomask

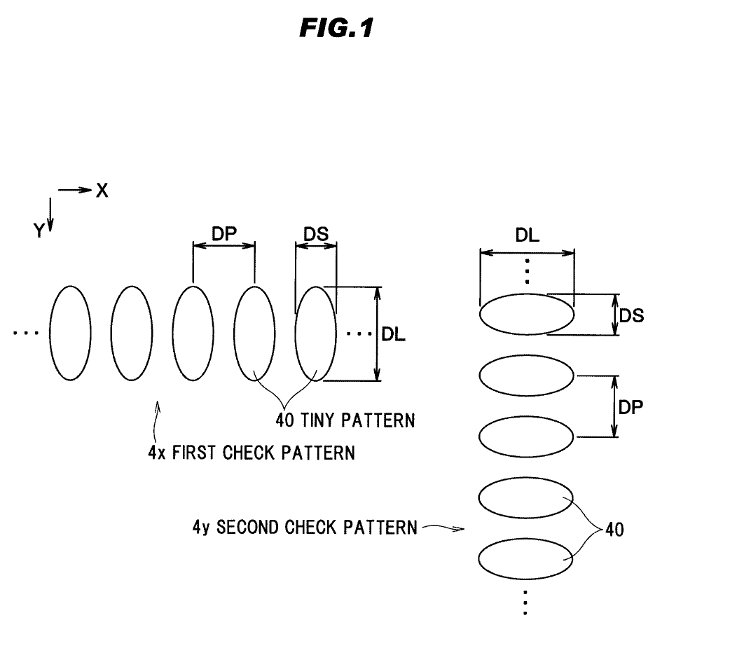

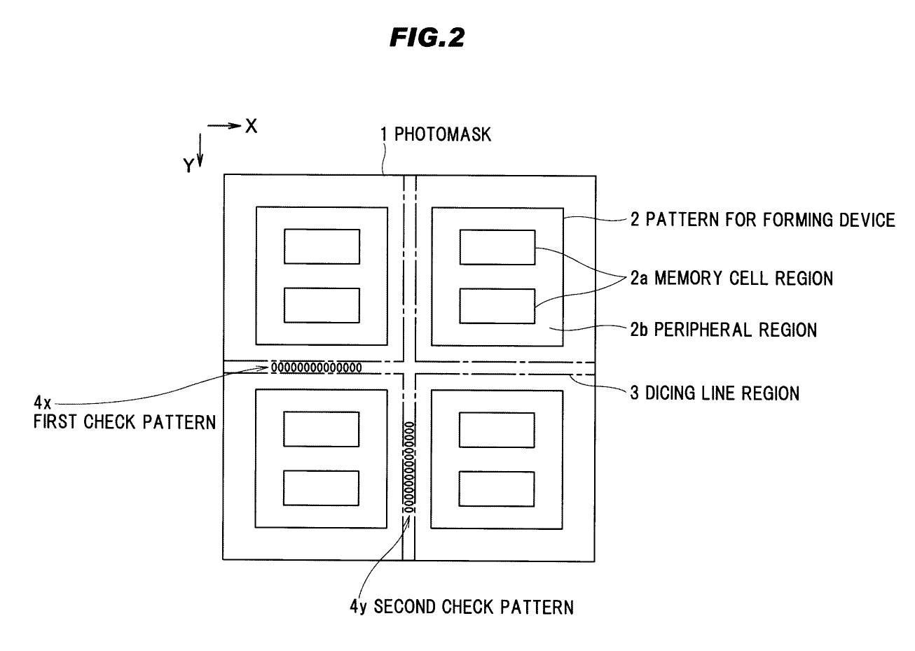

FIG. 1 is a plane view schematically showing one example of a main part of a check pattern used in the embodiment and FIG. 2 is a plane view schematically showing one example of a photomask used in the embodiment. Further, in FIGS. 1 to 2, each of X and Y shows a direction perpendicular to each other.

As shown in FIG. 1, the check pattern used in the embodiment includes a first check pattern 4x along the X direction and a second check pattern 4y along the Y direction. The first check pattern 4x has a structure that a plurality of tiny patterns 40 which have a first diameter (a long diameter) DL in the Y direction and a second diameter (a short diameter) DS in the X direction are arranged in the X direction at a pitch of DP. The second check pattern 4y has a structure that a plurality of tiny patterns 40 which have a first diameter (a long diameter) DL in the X direction and a second diameter (a short diameter) DS in the Y direction are arranged in the Y direction at a pitch of DP.

It is only necessary for each of the first and second check patterns 4x, 4y to have at least two arranged tiny patterns 40. Further, the tiny patterns 40 may be arranged in a plurality of rows. The shape of the tiny patterns 40 is not limited to an elliptic shape, and the other shapes such as an oval shape, a rectangular shape, a square shape, a perfectly circular shape can be also used. Further, as to the shape of the tiny pattern 40, here, a case that the first diameter is longer than the second diameter is assumed, however, another case that the second diameter is longer than the first diameter can be also used. Furthermore, in the embodiment, a case that the tiny pattern 40 is formed as a part to be passed by a light is assumed, however, an adverse case that the tiny pattern 40 is formed as a part to shield a light and the peripheral part is formed as a part to be passed by a light may be also adopted.

First, a photomask for checking which has the check patterns 4x, 4y shown in FIG. 1 optimizes the above-mentioned three parameters DL,DS,DP by optical proximity correction so that the check patterns 4x, 4y can be transferred at a desired dimension in a desired region, in case that an exposure is applied to a photoresist (a transferred member) on a substrate under optimum exposure conditions of the photomask used for fabricating a semiconductor device. Further, here, the optical proximity correction means a general optical proximity correction process that the mask pattern is designed in a state that the correction for the optical proximity is preliminarily applied to the pattern, in case of preparing data for generating a photomask pattern from design circuit pattern data desired to be formed on the photoresist, considering an effect that the shape of the pattern is changed on the photoresist due to the fact that the photomask pattern receives an optical proximity effect at the exposure. It is preferable that the above-mentioned parameters DL,DS,DP satisfy a relationship represented by a formula of, for example, DP<2DL. DP is set to be equal to, for example, a pitch of a line and space pattern (hereinafter referred to as “LS pattern”) on a photomask for forming a device pattern described below.

Next, as shown in FIG. 2, the check patterns 4x, 4y obtained by the optimization are disposed in a dicing line region 3 of a photomask 1 used for fabricating a semiconductor device. Here, the dicing line means a linear region that is cut off when a substrate on which a circuit has been formed is made into chips. The dicing line region 3 is a region corresponding to the dicing line of almost 100 μm in width on the substrate, and in case of using an exposure device carrying out a projection reduced to ¼, the dicing line region 3 has a width of almost 400 μm. In the photomask 1 shown in FIG. 2, the dicing line region 3 is disposed between patterns 2 for forming a device, and the first and second check patterns 4x, 4y are formed on the dicing line region 3. The pattern 2 for forming a device is, for example, a circuit pattern for forming a NAND-type flash memory as a semiconductor device, and includes a plurality of memory cell regions 2a and a peripheral region 2b formed at the periphery of the respective memory cell regions 2a. Further, the check patterns 4x, 4y can be formed in regions other than the dicing line region 3.

The memory cell region 2a includes a LS pattern (an X direction pattern) for forming a gate electrode in which a plurality of line patterns are arranged in the X direction and a LS pattern (a Y direction pattern) for forming an isolation trench in which a plurality of line patterns are arranged in the Y direction.

### (2) Transfer of Mask Pattern

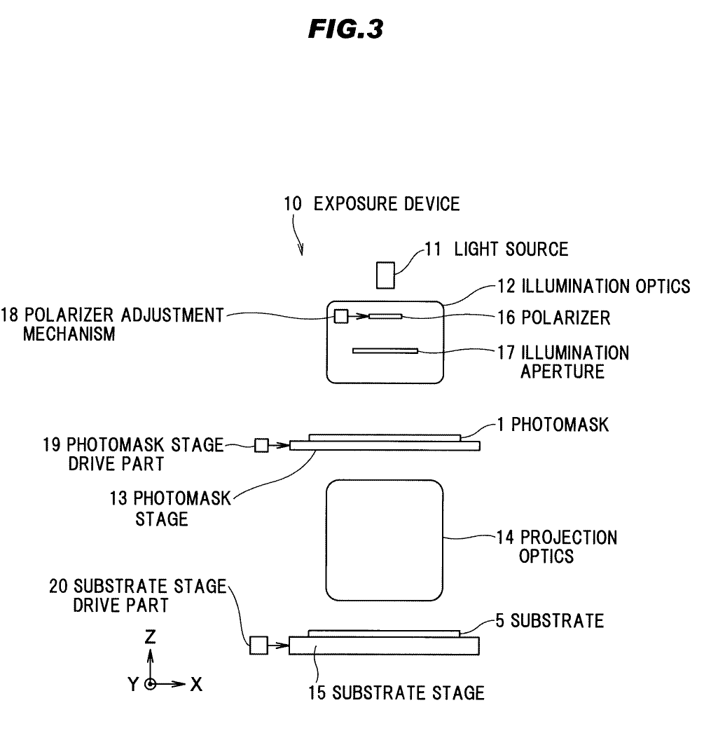

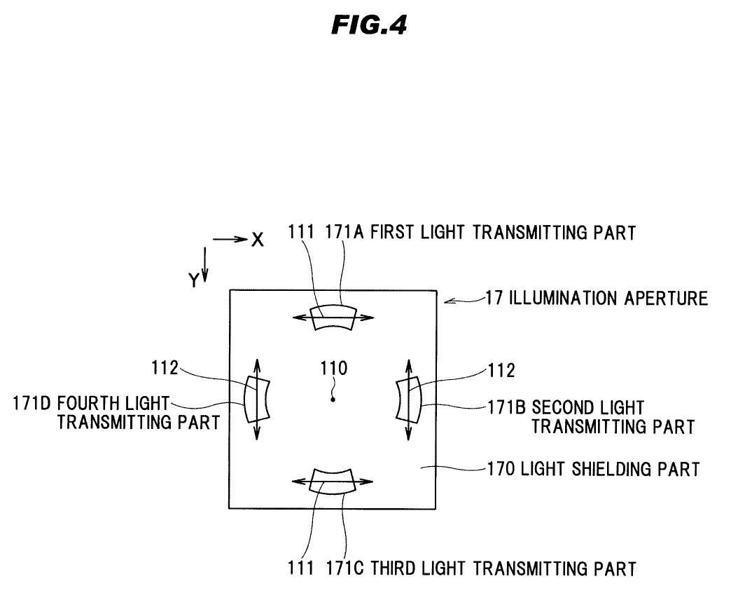

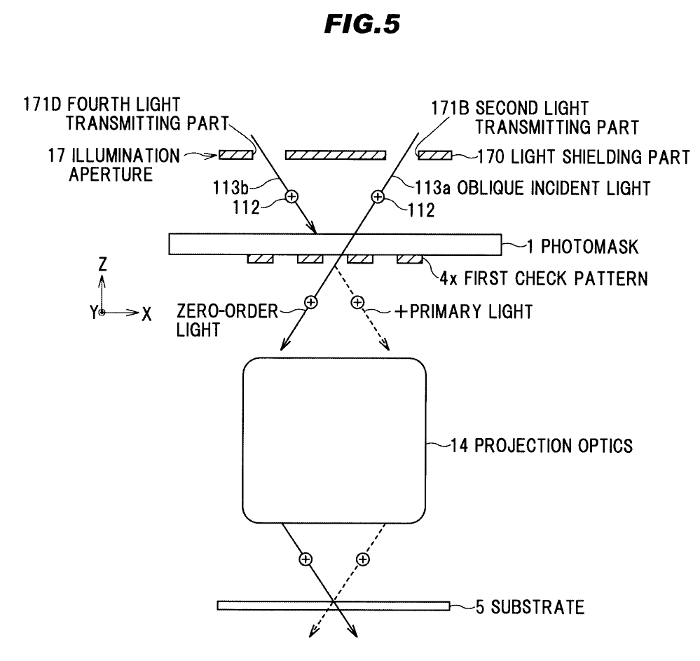

FIG. 3 is an explanatory view schematically showing one example of a structure of an exposure device used in the embodiment, FIG. 4 is a plane view schematically showing one example of an illumination aperture used in the embodiment and FIG. 5 is an explanatory view schematically showing a principle of two-beam interference. Further, in FIG. 3, each of X, Y and Z shows a direction perpendicular to each other.

As shown in FIG. 3, an exposure device 10 includes a light source 11 for emitting an illumination light, an illumination optics 12 for irradiating the photomask 1 with the illumination light emitted from the light source 11, a photomask stage 13 on which the photomask 1 is disposed, a projection optics 14 for projecting a light transmitted through the photomask 1 on a substrate 5 and a substrate stage 15 on which the substrate 5 is disposed.

As the light source 11, for example, an excimer laser for emitting a deep-ultraviolet (DUV) light having a wavelength of 248 nm, 193 nm and the like can be used. Further, the light source 11 is not limited to a light source emitting the DUV light, and can include a light source for emitting an ultraviolet (i line) light having a wavelength of 365 nm and a light source for emitting an extreme ultraviolet (EUV) light having a wavelength of 10 to 20 nm.

The illumination optics 12 includes a polarization optical element (a polarizer or a wavelength plate) 16 for obtaining a “s” polarized light from the illumination light of the light source 11, and an illumination aperture 17 disposed on a secondary light source surface and used for forming a secondary light source based on a quadrupole illumination. The polarization optical element 16 is connected to a polarization optical element adjustment mechanism 18 for adjusting the location of the polarization optical element 16 so as to adjust the polarization direction of the illumination light. Here, the “s” polarized light means a polarized light that the vibration direction of electrical vector is perpendicular to the incident surface. Further, here, the illumination aperture is used for forming the secondary light source, but a diffraction optical element including a diffraction grating and a lens can be also used.

The photomask stage 13 is formed so as to be movable in the X direction and Y direction, and the photomask stage 13 is connected to a photomask stage drive part 19 for moving the photomask 1 in the X direction and Y direction.

The substrate stage 15 is formed so as to be movable in the X direction and Y direction, and the substrate stage 15 is connected to a substrate stage drive part 20 for moving the substrate 5 in the X direction and Y direction.

As shown in FIG. 4, the illumination aperture 17 includes a light shielding part 170 having a rectangular shape and four (first to fourth) light transmitting parts 171A, 171B, 171C, 171D d disposed at even intervals with a central focus on a light axis 110. Polarization directions 111, 112 exist in the direction of the tangent to a circle having the light axis 110 as the center. Namely, lights transmitted through the first and third light transmitting parts 171A, 171C disposed at lengthways symmetric position to the light axis 110 have the polarization direction 111 directed in the X direction. Lights transmitted through the second and fourth light transmitting parts 171B, 171D disposed at sideways symmetric position to the light axis 110 have the polarization direction 112 directed in the Y direction. Further, depending on the patterns for forming a device, the other modified illumination such as a double polar illumination can be also used. In case of using the double polar illumination, one of the check patterns 4x, 4y corresponding to one of the X direction and Y direction included in the patterns for forming a device is used. In case that the diffraction optical element is used instead of the illumination aperture, a reference number of 170 represents a light-nonemission region and each of reference numbers of 171A to 171D represents a light-emission region.

The mask pattern of the photomask 1 is transferred onto the substrate 5 by using the exposure device 10 configured as described above. The illumination light emitted from the light source 11 is converted to the “s” polarized light by the polarization optical element 16 so as to form the secondary light source based on the quadrupole illumination on the secondary light source surface by the illumination aperture 17.

Subsequently, as shown in FIG. 5, a pair of oblique incident lights 113a, 113b based on the “s” polarized light which is transmitted through the second and fourth light transmitting parts 171B, 171D of the secondary light source and obliquely enters into the photomask 1 is diffracted at the first check patterns 4x aligned in the X direction of the mask pattern of the photomask 1 and the X direction pattern included in the patterns 2 for forming a device, so that, for example, a pattern is formed in a resist on the substrate 5 due to the two-beam interference between a zero-order light and one of a +primary light or a −primary light which contribute to the image formation. Similarly, a pair of oblique incident lights based on the “s” polarized light which is transmitted through the first and third light transmitting parts 171A, 171D of the secondary light source is diffracted at the second check patterns 4y aligned in the Y direction of the mask pattern of the photomask 1 and the Y direction pattern included in the patterns 2 for forming a device, so that, for example, a pattern is formed in a resist on the substrate 5 due to the two-beam interference between a zero-order light and one of a +primary light or a −primary light which contribute to the image formation.

### (3) Dimension Measurement of Resist Pattern

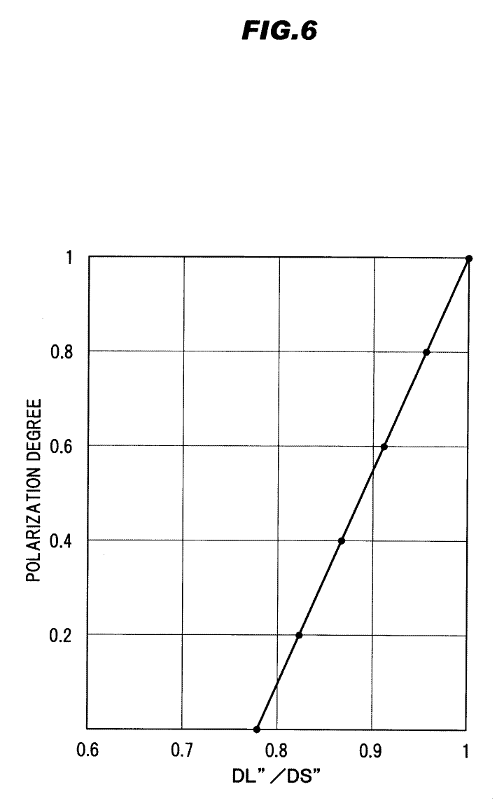

FIG. 6 is a graph schematically showing a polarization degree-dependency of the check pattern. Here, in order to distinguish between the dimension of the photomask and the dimension of the resist pattern, the long diameter of the resist pattern is defined as DL′ and the short diameter thereof is defined as DS′. Further, using the long diameter (a predetermined long diameter) of the resist pattern when the polarization degree is 1 as a basis, the dimension of the long diameter actually measured which is represented by rate of change, for example, percentage change is defined as DL″, and using the short diameter (a predetermined short diameter) of the resist pattern when the polarization degree is 1 as a basis, the dimension of the short diameter actually measured which is represented by rate of change, for example, percentage change is defined as DS″. In FIG. 6, the lateral axis shows a ratio DL″/DS″ of the long diameter DL″ to the short diameter DS″, and the longitudinal axis shows the polarization degree of the “s” polarization component. Here, the polarization degree of the “s” polarization component means a ratio of light intensity of the “s” polarization component to all light intensities of the light irradiating the photomask 1. Namely, if the intensity of the “s” polarization component is defined as Is and the intensity of the “p” polarization component is defined as Ip, the polarization degree of the “s” polarization component can be represented by a formula of Is/(Is+Ip), and the polarization degree of the “P” polarization component can be represented by a formula of Ip/(Is+Ip).

Next, the dimensions of the long diameter DL′ and the short diameter DS′ of the resist pattern on the substrate 5 onto which the mask pattern is transferred are measured by using a scanning electron microscope (SEM) or the like so as to calculate the DL″/DS″. Further, for measuring the dimensions of the long diameter DL′ and the short diameter DS′, all tiny patterns in the resist pattern can be measured and a part of tiny patterns can be also measured. Here, in order to obtain the dimensions of the long diameter DL′ and the short diameter DS′ with high accuracy, it can be also adopted to measure a large number of the tiny patterns and estimate the most probable value by statistical processing. Furthermore, the dimensions of the long diameter DL′ and the short diameter DS′ can be measured per formation of a plurality of the resist patterns, namely, per a certain number of the exposure, or can be also measured per a day, namely, per a certain period.

Further, the dimensions of the long diameter DL′ and the short diameter DS′ of the resist pattern on the substrate 5 onto which the mask pattern is transferred can be also measured by using a checking device for detecting a scattering light by irradiating the resist pattern with the incident light, instead of the scanning electron microscope (SEM). In this case, DL′ and DS′ of the check pattern can be specified and DL″/DS″ can be calculated by that the scattering light information is preliminarily prepared, the information corresponding to a case of irradiating the resist pattern whose DL′ and DS′ has been already known with the incident light, and including items of scattering angle, intensity and phase of the scattering light, and the above-mentioned scattering light information is crosschecked with scattering light information actually obtained. In case of using the checking method, it is preferable that the check patterns are evenly arranged in an adequately wide area so that the check patterns exist over the entire irradiation area of the incident light. Typically, the patterns can be evenly arranged in a region of the square of 40 μm.

Further, the dimensions of the long diameter DL′ and the short diameter DS′ of the resist pattern on the substrate 5 onto which the mask pattern is transferred can be also measured by using a checking method based on a so-called Die-to-Database system instead of the above-mentioned method using the scanning electron microscope (SEM) in which the dimensions of the check patterns are directly measured point by point, the checking method based on the Die-to-Database system, for example, obtaining electron microscope images of all the check patterns to be measured, saving the images and carrying out the pattern matching with the image information preliminarily stored, so as to collectively extract necessary dimension information. In this case, difference between the images preliminarily stored on the database and the images actually obtained is output, so that DL″ and DS″ can be obtained and DL″/DS″ can be calculated from the difference as the necessary dimension information.

Next, with reference to FIG. 6, it is judged whether all of the DL″/DS″ calculated are within a span of control, and if within the span of control, the exposure of the substrate 5 to be used for fabricating a semiconductor device is continuously carried out. For example, if a formula of (DL″/DS″)>0.9 (polarization degree>almost 0.6) is adopted as an admissibility condition, when DL″/DS″ is 0.95 it is judged as within the span of control, and when DL″/DS″ is 0.85 it is judged as beyond the span of control. Further, it can be also adopted that average values of the long diameter DL′ and the short diameter DS′ of each of the first check pattern 4x and the second check pattern 4y are calculated and it is judged whether the DL″/DS″ calculated from the respective average values is within a span of control.

If DL″/DS″ is within a span of control, the exposure of the substrate 5 to be used for fabricating a semiconductor device is discontinued, the polarization degree is adjusted to the exposure device 10. After the adjustment is completed, the exposure of the substrate 5 to be used for fabricating a semiconductor device is started again.

The polarization degree is degraded dependent on change in optical property (birefringence) of, change in antireflection film of surface of the optical members, displacement of the polarization optical element 16 and the like, so that the adjustment of the polarization degree is carried out by replacement of the optical members in the illumination optics 12, position adjusting of the polarization optical element 16 by the polarization optical element adjustment mechanism 18 or the like.

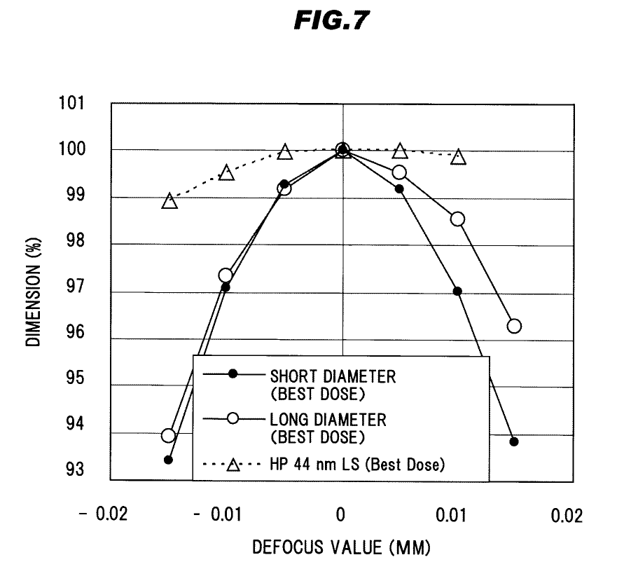

FIG. 7 is a graph schematically showing a defocus value-dependency of the check pattern. In FIG. 7, the lateral axis shows a defocus value, and the longitudinal axis shows a dimension (a value obtained in case that each of the short diameter, long diameter, and dimension of line width of the LS pattern of the check pattern on the substrate is represented in percentage, using the value at the best focus as a basis). Further, FIG. 7 shows a measurement result obtained when the parameters of the check pattern on the substrate are specified as the long diameter DL′=100 nm, the short diameter DS′=44 nm and the pitch DP′=88 nm, and the dimension of line width of the LS pattern of the pattern for forming a device is specified as 44 nm. As is clear from FIG. 7, it is known that if the defocus value is displaced from the best focus value (0 μm), the short diameter and long diameter of the check pattern tend to be reduced. The line width of the LS pattern also tends to be reduced, but the check pattern has higher sensitivity than the LS pattern has. Further, of the check pattern, the dimension of short diameter has higher sensitivity than the dimension of long diameter has.

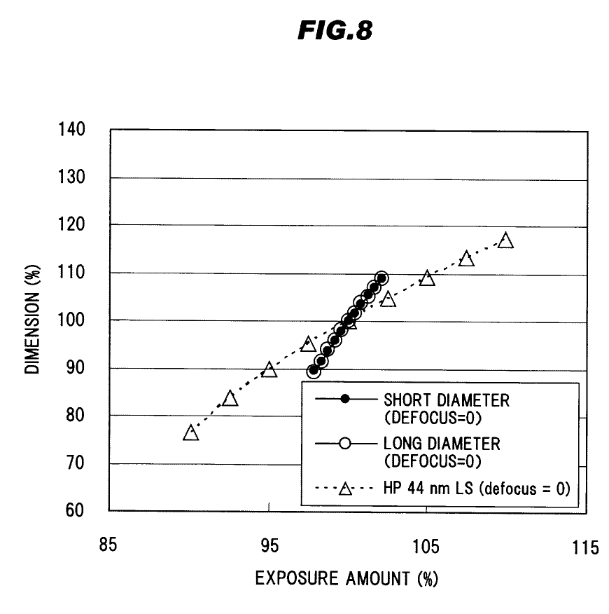

FIG. 8 is a graph schematically showing an exposure amount-dependency of the check pattern. In FIG. 8, the lateral axis shows an exposure amount (a value obtained in case of being normalized based on defining the best exposure amount as 100%), and the longitudinal axis shows a dimension (a value obtained in case that each of the short diameter, long diameter, and dimension of line width of the LS pattern of the check pattern on the substrate is represented in percentage, using the value at the best focus as a basis). Further, FIG. 7 shows a measurement result obtained when the parameters of the check pattern and the dimension of line width of the LS pattern are specified so as to become the same values as those of a case of FIG. 7. As is clear from FIG. 8, it is known that as the exposure amount is increased or decreased from the best exposure amount (100%), the short diameter and long diameter of the check pattern tend to be increased or decreased. The line width of the LS pattern also tends to be increased or decreased as the exposure amount is increased or decreased, but the check pattern has higher sensitivity than the LS pattern has. As seen from the above, the check pattern can be monitored about the focus value and the displacement of exposure amount with higher sensitivity than that of the pattern for forming a device.

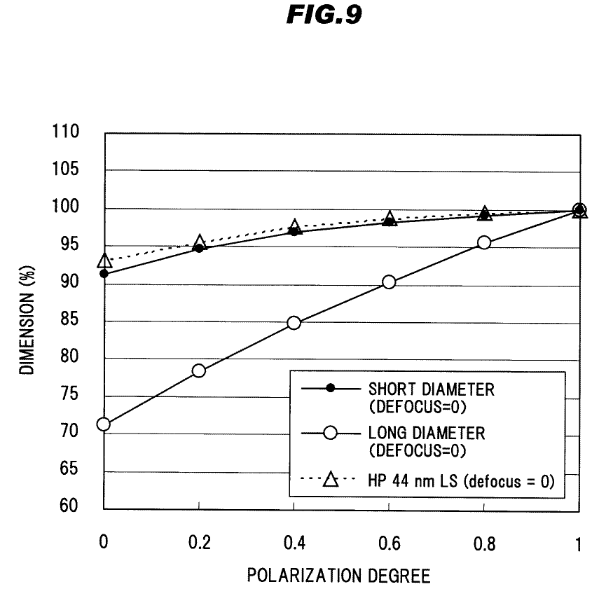

FIG. 9 is a graph schematically showing a polarization degree-dependency of the check pattern. In FIG. 9, the lateral axis shows a polarization degree, and the longitudinal axis shows a dimension (a value obtained in case that each of the short diameter, long diameter, and dimension of line width of the LS pattern of the check pattern on the substrate is represented in percentage, using the value when the polarization degree is 1 as a basis). Further, FIG. 9 shows a measurement result obtained when the parameters of the check pattern and the dimension of line width of the LS pattern are specified so as to become the same values as those of a case of FIG. 7. As is clear from FIG. 8, it is known that as the polarization degree is degraded, the short diameter and long diameter of the check pattern are reduced together, but the long diameter is more largely decreased than the short diameter.

With regard to the change in the focus, the short diameter is more largely changed than the long diameter, which is opposite to the change in polarization degree, and with regard to the change in the exposure amount, the long diameter and the short diameter are similarly changed in dimension. Therefore, as shown in FIG. 6, by examining the ratio between the rate of change of the long diameter and the rate of change of the short diameter, the degradation of polarization degree can be detected, independently of displacement of the focus and change in the exposure amount.

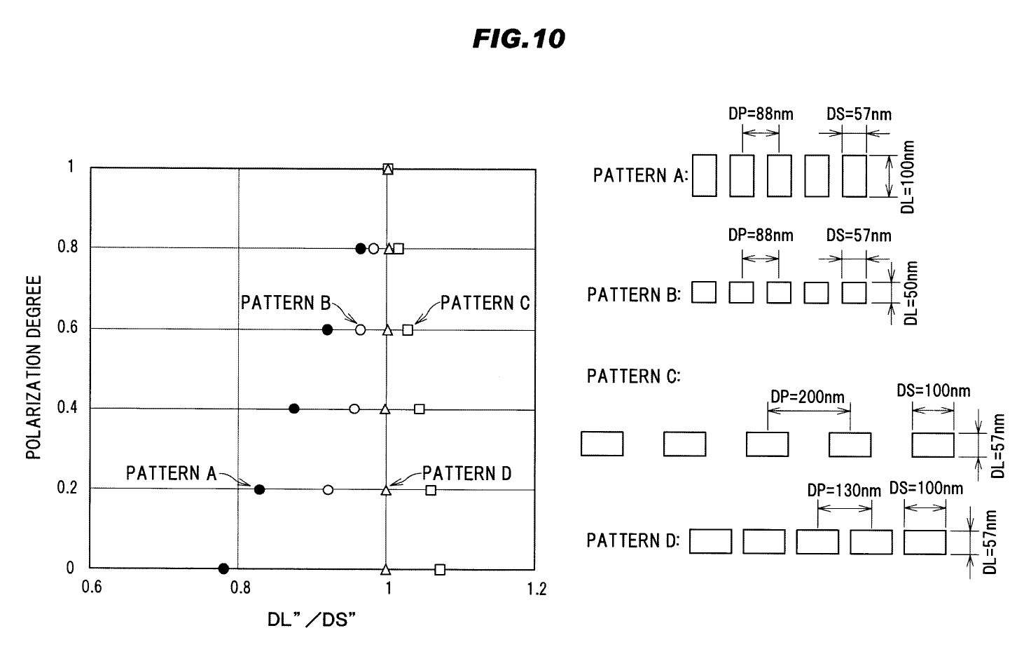

FIG. 10 is a graph schematically showing a polarization degree-dependency of the other check pattern. Here, in order to distinguish between the dimension of the photomask and the dimension of the resist pattern, the first diameter of the resist pattern is defined as DL′ and the second diameter thereof is defined as DS′. Further, using the first diameter of the resist pattern when the polarization degree is 1 as a basis, the dimension of the second diameter actually measured which is represented by percentage change is defined as DL″, and using the second diameter of the resist pattern when the polarization degree is 1 as a basis, the dimension of the second diameter actually measured which is represented by percentage change is defined as DS″. In FIG. 10, the lateral axis shows a ratio DL″/DS″ of the second diameter DL″ to the second diameter DS″, and the longitudinal axis shows the polarization degree of the “s” polarization component. FIG. 10 shows a relationship between the DL″/DS″ and the polarization degree with regard to the patterns A, B, C, D. The pattern A is formed so as to have a structure that the first diameter is larger than the second diameter, the pattern B is formed so as to have a structure that the first diameter is smaller than that of the pattern A, the pattern C is formed so as to have a structure that the first diameter is the long diameter and the second diameter is the short diameter and the pattern D is formed so as to have a structure that the pitch is smaller than that of the pattern C. A result was obtained that the pattern A has the gentlest inclination,of the patterns A, B, C, D. Namely, it can be said that the pattern A is resistant to error of the DL″/DS″ and is the most excellent as the check method.

### Advantages of Embodiment

According to the Embodiment, the following advantages can be provided.
(1) The pattern to be used for fabricating a semiconductor device and the check pattern are simultaneously formed on the substrate so that it is not needed to place a light detector in a light path for measuring the polarization degree, reduction of the productivity of exposure device can be prevented.
(2) The ratio between the rate of change of the long diameter and the rate of change of the short diameter in the tiny pattern are calculated so that the degradation of polarization degree can be examined independently of variations of the focus and the exposure amount.
(3) Together with the line and space pattern to be used for fabricating a semiconductor device, the check pattern is formed on the photomask so that a photomask especially used for the check can be made unnecessary.

Further, it should be noted that the present invention is not intended to be limited to the above-mentioned embodiment, and the various kinds of changes thereof can be implemented by those skilled in the art without departing from the gist of the invention.

For example, in the above-mentioned embodiment, the exposure using the “s” polarized light has been explained, but the invention can be also applied to the exposure using an illumination light in an arbitrary polarization condition, such as a not-polarized light, the “p” polarized light.

What is claimed is:

1. A method of controlling exposure device, comprising:
preparing a photomask in which a check pattern is formed, wherein the check pattern comprising a plurality of patterns which have a first diameter and a second diameter and have pattern dimensions being changeable after being transferred according to polarization degree of exposure light are arranged in the second diameter direction;
irradiating the photomask with the exposure light having a predetermined polarization degree so as to transfer the check pattern to a transferred object; and
measuring the dimensions of the images of the check pattern transferred to the transferred object so as to obtain the polarization degree.

2. The method of controlling exposure device according to claim 1, wherein,
the exposure light is formed along the second diameter direction of the check pattern, and is emitted from a secondary light source having a plurality of bright sections symmetrically-positioned to the light axis.

3. The method of controlling exposure device according to claim 1, wherein,
the first diameter which the patterns of the check pattern have is a long diameter, and the second diameter which the patterns have is a short diameter.

4. The method of controlling exposure device according to claim 3, wherein,
if the first diameter is defined as DL and the pitch between the patterns is defined as DP, a relationship represented by a formula of DP<2DL is satisfied.

5. The method of controlling exposure device according to claim 3, wherein,
the polarization degree is obtained by using information that shows a relationship between a ratio of percentage change of the long diameter obtained by the measurement of dimensions on the basis of a predetermined long diameter to percentage change of the short diameter obtained by the measurement of dimensions on the basis of a predetermined short diameter, and the polarization degree.

6. The method of controlling exposure device according to claim 3, wherein,
the polarization degree is obtained by using information that shows a relationship between percentage change of the long diameter obtained by the measurement of dimensions on the basis of a predetermined long diameter and the polarization degree.

7. The method of controlling exposure device according to claim 1, wherein,
the check pattern formed in the photomask comprises a first check pattern and a second check pattern which are disposed so that the arranging directions of a plurality of the patterns are perpendicular to each other.

8. The method of controlling exposure device according to claim 1, wherein,
the photomask comprises a device pattern having a line and space pattern in which a plurality of line patterns are arranged in the direction of the second diameter of the check pattern.

9. The method of controlling exposure device according to claim 8, wherein,
the pitch between the line patterns constituting the line and space pattern is equal to the pitch between the patterns constituting the check pattern.

10. The method of controlling exposure device according to claim 1, wherein,
the photomask has a structure that the check pattern is formed in a dicing line region.

11. The method of controlling exposure device according to claim 1, wherein,
the check pattern is transferred to the transferred object by irradiating the photomask with “s” polarized light as the exposure light having a predetermined polarization degree.

12. A method of fabricating a semiconductor device, comprising:
forming a device pattern on a wafer by using an exposure device in which the polarization degree is controlled by the method of controlling exposure device according to claim 1.

13. The method of fabricating a semiconductor device according to claim 12, wherein,
the device pattern comprises a line and space pattern in which a plurality of line patterns are arranged in the direction of the second diameter of the check pattern.

14. A photomask, comprising:
a device pattern having a line and space pattern arranged in a predetermined direction; and
a check pattern comprising a plurality of patterns which have a first diameter and a second diameter and are arranged so as to match the second diameter direction to the predetermined direction.

15. The photomask according to claim 14, wherein,
the first diameter which the patterns of the check pattern have is a long diameter, and the second diameter which the patterns have is a short diameter.

16. The photomask according to claim 15, wherein,
if the first diameter is defined as DL and the pitch between the patterns is defined as DP, a relationship represented by a formula of DP<2DL is satisfied.

17. The photomask according to claim 14, wherein,
the check pattern formed in the photomask comprises a first check pattern and a second check pattern which are disposed so that the arranging direction of a plurality of the patterns are perpendicular to each other.

18. The photomask according to claim 14, wherein,
the photomask comprises a device pattern having a line and space pattern in which a plurality of line patterns are arranged in the direction of the second diameter of the check pattern.

19. The photomask according to claim 18, wherein,
the pitch between the line patterns constituting the line and space pattern is equal to the pitch between the patterns constituting the check pattern.

20. The photomask according to claim 14, wherein,
the check pattern is formed in a dicing line region.
